(19) United States
(12) Patent Application Publication
(10) Pub. No.: US 2014/0022023 A1
(43) Pub. Date: Jan. 23, 2014

(54) TEMPERATURE-INSENSITIVE RING OSCILLATORS AND INVERTER CIRCUITS

(71) Applicant: MediaTek Inc., Hsin-Chu (TW)

(72) Inventor: Hsien-Sheng HUANG, Hsinchu City (TW)

(21) Appl. No.: 13/922,829

(22) Filed: Jun. 20, 2013

Related U.S. Application Data
(60) Provisional application No. 61/673,862, filed on Jul. 20, 2012.

(51) Int. Cl. H03K 3/03

(52) U.S. Cl. CPC H03K 3/0315
USPC 331/57

(57) ABSTRACT

A ring oscillator includes a plurality of stages of delay cells coupled in serial. At least one delay cell includes a first inverter. The first inverter includes an input node receiving an input signal, a first transistor coupled to a first supply voltage and the input node, a second transistor coupled to a second supply voltage and the input node, an output node coupled to the first transistor and the second transistor and outputting an output signal, and at least one resistive device coupled to the capacitor, the first transistor, and the second transistor.

### CROSS REFERENCE TO RELATED APPLICATIONS

This application claims the benefit of U.S. Provisional Application No. 61/673,862, filed Jul. 20, 2012 and entitled “LOW-GAIN AND TEMPERATURE-INSENSITIVE RING OSCILLATOR”, the entire contents of which are hereby incorporated by reference.

### BACKGROUND OF THE INVENTION

1. Field of the Invention

The invention relates to a ring oscillator, and more particularly to a stable, low-gain, and temperature-insensitive ring oscillator.

2. Description of the Related Art

An oscillator is used in electronic circuits to generate precise clock signals. However, the oscillation frequency of an oscillator is generally unstable. In particular, the oscillation frequency varies with ambient temperature and supply-voltage drift, which affects the operation of the device.

Thus, it is desirable to design a novel ring oscillator with low-gain and temperature-insensitive properties.

### BRIEF SUMMARY OF THE INVENTION

Ring oscillators and inverter circuits are provided. An exemplary embodiment of a ring oscillator comprises a plurality of stages of delay cells coupled in serial. At least one delay cell comprises a first inverter. The first inverter comprises an input node receiving an input signal, a first transistor coupled to a first supply voltage and the input node, a second transistor coupled to a second supply voltage and the input node, an output node coupled to the first transistor and the second transistor and outputting an output signal, and at least one resistive device coupled to the capacitor, the first transistor, and the second transistor.

An exemplary embodiment of an inverter circuit comprises an input node receiving an input signal, a first transistor coupled to a first supply voltage and the input node, a second transistor coupled to a second supply voltage and the input node, an output node coupled to the first transistor and the second transistor and outputting an output signal complementary to the input signal, and at least one resistive device contributing resistance on a charge path when charging the capacitor or a discharge path when discharging the capacitor.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a block diagram of a ring oscillator according to an embodiment of the invention;

FIG. 2 shows a circuit diagram of an inverter circuit according to an embodiment of the invention;

FIG. 3 shows a circuit diagram of an inverter circuit according to another embodiment of the invention;

FIG. 4 shows a circuit diagram of an inverter circuit according to yet another embodiment of the invention;

FIG. 5 shows a circuit diagram of an inverter circuit according to yet another embodiment of the invention;

FIG. 6 shows a circuit diagram of an inverter circuit according to yet another embodiment of the invention;

FIG. 7 is a block diagram of a ring oscillator according to another embodiment of the invention; and

FIG. 8 shows a circuit diagram of a differential delay cell according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

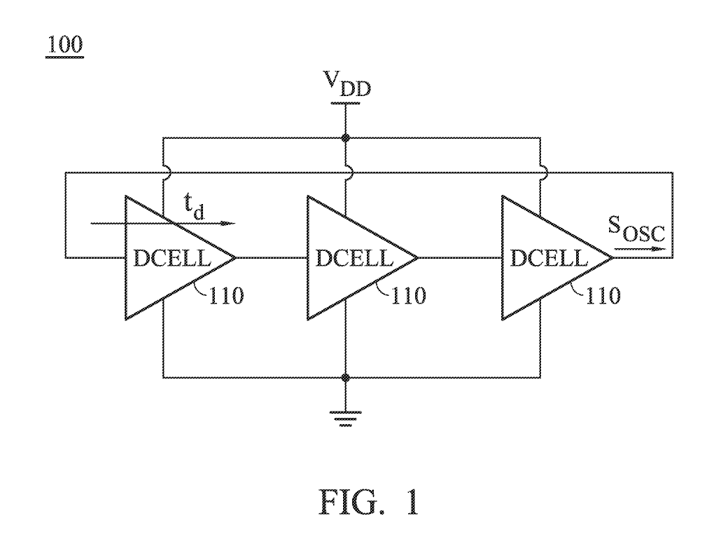

FIG. 1 is a block diagram of a ring oscillator according to an embodiment of the invention. According to an embodiment of the invention, the ring oscillator 100 may comprise a plurality of stages of single-ended delay cells DCELL 110 coupled in serial. An output node of each delay cell stage is coupled to an input node of a following delay cell stage. Suppose the delay time of each delay cell is t_{d}, a period T of the oscillating signal S_{OSC} generated by the ring oscillator 100 may be derived as T=6*t_{d}. In this example, there are three stages of delay cells comprised in the ring oscillator 100. It should be noted that the ring oscillator 100 may also comprise less than or more than three stages of delay cells, and therefore, the invention should not be limited to the structure as shown in FIG. 1.

According to a preferred embodiment of the invention, the delay cells 110 may comprise at least an R-inverter, which is an inverter with at least one resistive device comprised therein. According to an embodiment of the invention, the resistive device may contribute a resistance on a charge path and/or a discharge path of the inverter circuit. The at least one resistive device may be utilized to reduce the sensitivity of the delay time t_{d} to the changes in supply voltage V_{DD} and temperature, resulting in a stable, low-gain and temperature-insensitive ring oscillator. Several embodiments of the proposed R-inverter are further discussed in the following paragraphs.

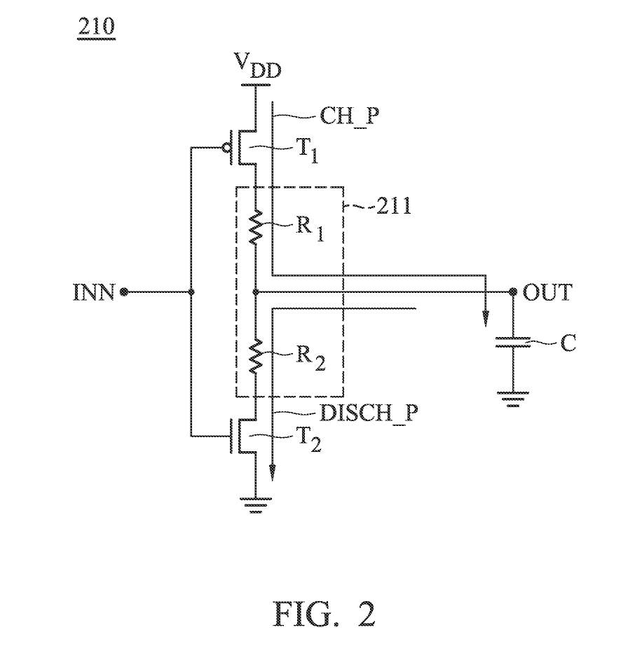

FIG. 2 shows a circuit diagram of an inverter circuit according to an embodiment of the invention. The inverter 210 may comprise an input node INN for receiving an input signal and an output node OUT for outputting an output signal, which may be complementary to the input signal. The inverter 210 may further comprise a transistor T₁ coupled to a supply voltage V_{DD} and the input node INN, a transistor T₂ coupled to a ground voltage and the input node INN, a capacitor C coupled between the output node OUT and the ground voltage and at least one resistive device 211 coupled to the capacitor C and the transistors T₁ and T₂. Note that in the embodiments of the invention, the capacitor C may be a real implementation of capacitor or a parasitic capacitor introduced by the next stage, and the invention should not be limited to either case. The next stage may be a load of the inverter. When looking from the output end of the inverter, the input end of the next stage would constitute a parasitic capacitor.

According to an embodiment of the invention, the resistive device 211 may be disposed on a charge path CH_P starting with the supply voltage V_{DD} through the transistor T₁ and the capacitor C to the ground voltage and/or a discharge path DISCH_P starting with the capacitor C through the transistor T₂ to the ground voltage. Note that the resistive device 211 may be disposed anywhere on the charge path CH_P and/or the discharge path DISCH_P, as long as the resistance can be contributed on the charge path CH_P of the inverter circuit when charging the capacitor C and the discharge path DISCH_P of the inverter circuit when discharging the capacitor C. In this embodiment as shown in FIG. 2, the resistive device 211 may at least comprise a resistor R₁ coupled between the output node OUT and the supply voltage V_{DD} and a resistor R₂ coupled between the output node OUT and the ground voltage.

To be more specific, the resistor R₁ may be electrically connected between a first electrode (for example, the drain) of the transistor T₁ and the output node OUT, the resistor R₂ may be electrically connected between a first electrode of the transistor T₂ and the output node OUT. Note that the placement of the resistors R₁ and R₂ may be symmetric as shown in FIG. 2, or may be asymmetric (for example, the R₁ may be electrically connected between the first electrode of the transistor T₁ and the output node OUT, while the R₂ may be electrically connected between a second electrode (for example, the source) of the transistor T₂ and the ground voltage, or others). Therefore, the structure shown in FIG. 2 is just a preferred embodiment and the invention should not be limited thereto.

According to an embodiment of the invention, the resistance contributed by the resistive device 211 may be designed to be greater than the turn-on resistance R_{ON1} of the transistor T₁ and the turn-on resistance R_{ON2} of the transistor T₂. Suppose that the resistance contributed by the resistive device 211 is R, and the turn-on resistance of the transistors T₁ and T₂ are both equal to R_{ON}, the delay time of the delay cell formed by the inverter 210 may be:

t_{d}≈RC time constant=(R+R_{ON})*C₁ Eq. (1)

where C₁ is the capacitance of the capacitor C, and the turn-on resistance R_{ON} may be represented as:

R_{ON}≈K*(V_{GS}−V_{TH}) Eq. (2)

where K is a constant, V_{TH} is the threshold voltage of the transistor T₁ and/or T₂, and V_{GS} is the gate-source voltage of the transistor T₁ and/or T₂. Since the voltage V_{GS} varies with the voltage of the input signal of the corresponding delay cell, the input signal of the delay cell is just the output signal, with voltage varying with the supply voltage V_{DD} of a previous stage delay cell. It is obvious that the voltage V_{GS} varies with the supply voltage V_{DD}. In other words, the turn-on resistance R_{ON} is very sensitive to the voltage change in the supply voltage V_{DD}.

Therefore, in the embodiments of the invention, it is preferable to design the R to be much greater than the turn-on resistance R_{ON} (i.e. R>>R_{ON}). In this manner, the delay time t_{d} can be as insensitive as possible to the voltage variance of the supply voltage V_{DD}. According to a preferred embodiment of the invention, a ratio of R:R_{ON} may be selected from 2:1˜6:1, so as to ensure that the delay time t_{d} will be almost insensitive to the voltage variance of the supply voltage V_{DD}.

As to the temperature variance, according to the embodiments of the invention, the resistance contributed by the resistive device 211 may be designed to have a temperature coefficient complementary to that of the turn-on resistance R_{ON} of the transistor T₁ and transistor T₂. To be more specific, when the turn-on resistance R_{ON} has a positive temperature coefficient K_{RON,} the resistance R may be designed to have a negative temperature coefficient K_{R}, so as to mutually eliminate the influence of the temperature variance on the delay time t_{d}. When the ratio of R:R_{ON} is properly designed, the resulting temperature coefficient of the delay time t_{d} may be very small. For example, the resistance R may be designed to satisfy the following equation:

|R*K_{R}|=|R_{ON}*K_{RON}| Eq. (3)

In this manner, the delay time t_{d} can be as insensitive as possible to the temperature variance. According to a preferred embodiment of the invention, a ratio of R:R_{ON}may be selected from 2:1 to 10:1, so that the delay time t_{d} will be almost insensitive to the temperature variance. Note that in other embodiments of the invention, depending on different design requirements, the ratio of R:R_{ON} may be designed in at different values. For example, it may also be possible for the ratio of R:R_{ON} to be 10000:1, or further 100000:1. Thus, in the embodiments of the invention, the ratio of R:R_{ON} may be selected to be from 2:1 to 100000:1.

Note that, unlike the conventional designs for ring oscillators in which an extra supply voltage is introduced to compensate for variation in supply voltage V_{DD} or temperature, the influence of the supply voltage V_{DD} and/or temperature variation is directly reduced or even eliminated via the proper design of the resistance of the resistive device disposed on the charge path CH_P and/or the discharge path DISCH_P of the proposed R-inverter. In addition, since the turn-on resistance R_{ON} is much smaller than the resistance R of the resistive device, the flicker noises caused by the transistors T₁ and T₂ can be smaller than in conventional designs.

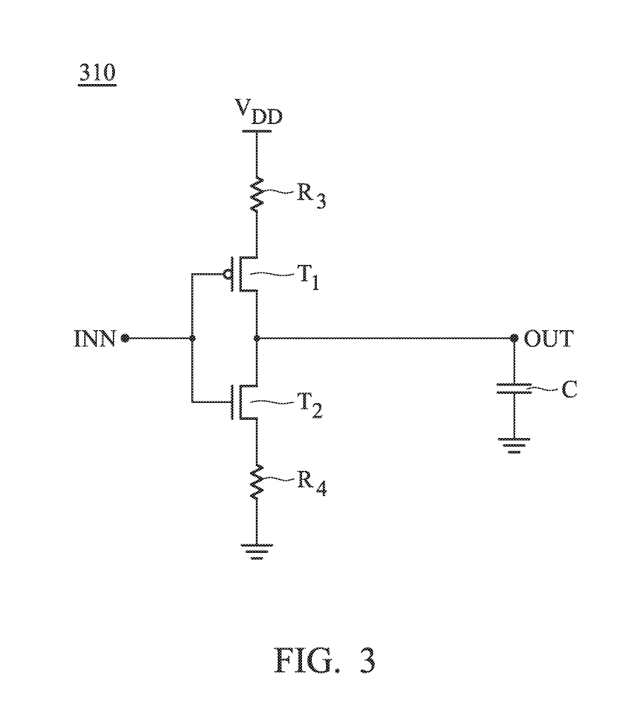

FIG. 3 shows a circuit diagram of an inverter circuit according to another embodiment of the invention. The inverter 310 has a similar structure to the inverter 210, with the difference being that the resistive device may comprise at least a resistor R₃ electrically connected between a second electrode of the transistor T₁ and the supply voltage V_{DD}, and a resistor R₄ electrically connected between a second electrode of the transistor T₂ and the ground voltage. Note that the placement of the resistors R₃ and R₄ may be symmetric as shown in FIG. 3, or may be asymmetric (for example, the R₃ may be electrically connected between the second electrode of the transistor T₁ and the supply voltage V_{DD}, while the R₂ may be electrically connected between the first electrode of the transistor T₂ and the output node OUT, or others). Therefore, the structure shown in FIG. 3 is just a preferred embodiment and the invention should not be limited thereto.

According to an embodiment of the invention, the resistance contributed by the resistive device comprising the resistors R₃ and R₄ may be designed to be much greater than the turn-on resistance R_{ON1} of the transistor T₁ and the turn-on resistance R_{ON2} of the transistor T₂. In this manner, the delay time t_{d} can be as insensitive as possible to the voltage variance of the supply voltage V_{DD}. In addition, according to the embodiments of the invention, the resistance contributed by the resistive device comprising the resistors R₃ and R₄ may be designed to have a temperature coefficient complementary to that of the turn-on resistance R_{ON} of transistor T₁ and transistor T₂, so as to mutually eliminate the influence of the temperature variance on the delay time t_{d}. When the ratio of R:R_{ON} is properly designed, the resulting temperature coefficient of the delay time t_{d} may be very small. In this embodiment, R may represent the resistance of the resistors R₃ and R_{4,} and R_{ON} may represent the turn-on resistance of the transistors T₁ and T₂. For detailed a discussion of the design of the resistors R₃ and R₄ disposed on the charge and discharge paths of the inverter circuit, reference may be made to the description of FIG. 2, which is omitted here for brevity.

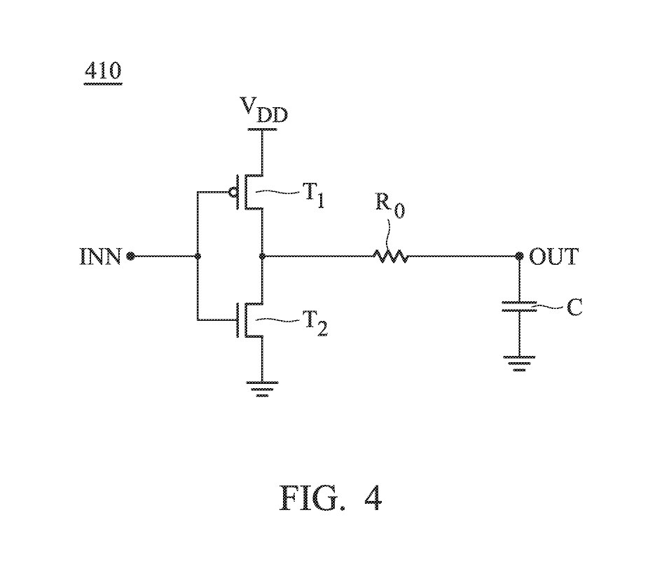

FIG. 4 shows a circuit diagram of an inverter circuit according to yet another embodiment of the invention. The inverter 410 has a similar structure to the inverter 210, the difference being that the resistive device may at least comprise a resistor R₀ coupled between the connection node of the first transistor and the second transistor and the output node OUT.

According to an embodiment of the invention, the resistance contributed by the resistive device comprising the resistor R₀ may be designed to be much greater than the turn-on resistance R_{ON1} of the transistor T₁ and the turn-on resistance R_{ON2} of the transistor T₂. In this manner, the delay time t_{d} can be as insensitive as possible to the voltage variance of the supply voltage V_{DD}. In addition, according to the embodiments of the invention, the resistance contributed by the resistive device comprising the resistor R₀ may be designed to have a temperature coefficient complementary to that of the turn-on resistance R_{ON} of the transistor T₁ and transistor T₂, so as to mutually eliminate the influence of the temperature variance on the delay time t_{d}. When the ratio of R:R_{ON} is properly designed, the resulting temperature coefficient of the delay time t_{d} may be very small. In this embodiment, R may represent the resistance of the resistor R₀ and R_{ON} may represent the turn-on resistance of the transistors T₁ and T₂. For a detailed discussion of the design of the resistor R₀ disposed on the charge and discharge paths of the inverter circuit, reference may be made to the description of FIG. 2, which is omitted here for brevity.

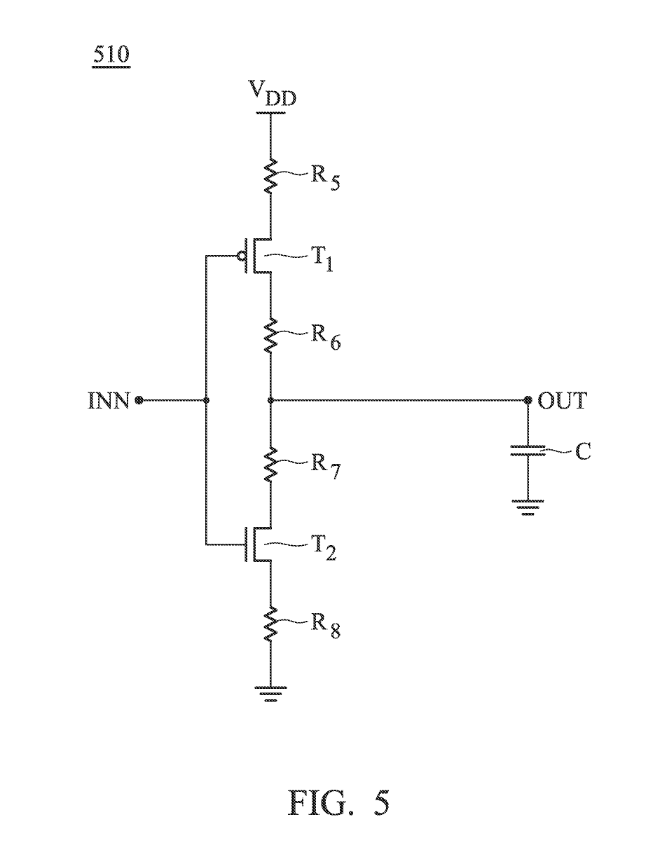

FIG. 5 shows the circuit diagram of an inverter circuit according to yet another embodiment of the invention. The inverter 510 has a similar structure to the inverter 210, the difference being that the resistive device may at least comprise resistors R₅ and R₆ coupled between the supply voltage V_{DD} and the output node OUT and resistors R₂ and R₈ coupled between the ground voltage and the output node OUT.

According to an embodiment of the invention, the resistance contributed by the resistive device comprising the resistors R₅˜R₈ may be designed to be much greater than the turn-on resistance R_{ON1} of the transistor T₁ and the turn-on resistance R_{ON2} of the transistor T₂. In this manner, the delay time t_{d} can be as insensitive as possible to the voltage variance of the supply voltage V_{DD}. In addition, according to the embodiments of the invention, the resistance contributed by the resistive device comprising the resistors R₅˜R₈ may be designed to have a temperature coefficient complementary to that of the turn-on resistance R_{ON} of the transistor T₁ and transistor T₂, so as to mutually eliminate the influence of the temperature variance on the delay time t_{d}. When the ratio of R:R_{ON} is properly designed, the resulting temperature coefficient of the delay time t_{d} may be very small. In this embodiment, R may represent a summation of the resistances of the resistors R₅ and R₆, or R₂ and R₈ and R_{ON} may represent the turn-on resistance of the transistors T₁ and T₂. For a detailed discussion of the designs the resistance R, reference may be made to the description of FIG. 2, which is omitted here for brevity.

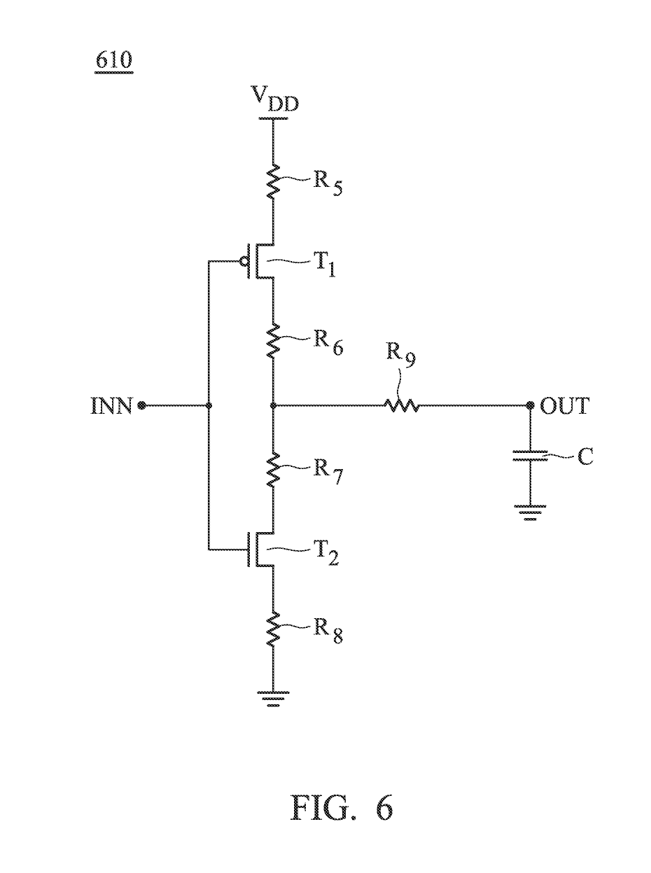

FIG. 6 shows a circuit diagram for an inverter circuit according to yet another embodiment of the invention. The inverter 610 has a similar structure to the inverter 510, the difference being that the resistive device may further comprise a resistor R₉ coupled between a connection node of the first transistor and the second transistor and the output node OUT.

According to an embodiment of the invention, the resistance contributed by the resistive device comprising the resistors R₅˜R₉ may be designed to be much greater than the turn-on resistance R_{ON1} of the transistor T₁ and the turn-on resistance R_{ON2} of the transistor T₂. In this manner, the delay time t_{d} can be as insensitive as possible to the voltage variance of the supply voltage V_{DD}. In addition, according to the embodiments of the invention, the resistance contributed by the resistive device comprising the resistors R₅˜R₉ may be designed to have a temperature coefficient complementary to that of the turn-on resistance R_{ON} of the transistor T₁ and transistor T₂, so as to mutually eliminate the influence of the temperature variance on the delay time t_{d}. When the ratio of R:R_{ON} is properly designed, the resulting temperature coefficient of the delay time t_{d} may be very small. In this embodiment, R may represent a summation of the resistances of the resistors R₅, R₆ and R₉, or R₇, R₈ and R₉ and R_{ON} may represent the turn-on resistance of the transistors T₁ and T₂. For a detailed discussion of the designs the resistance R, reference may be made to the description of FIG. 2, which is omitted here for brevity.

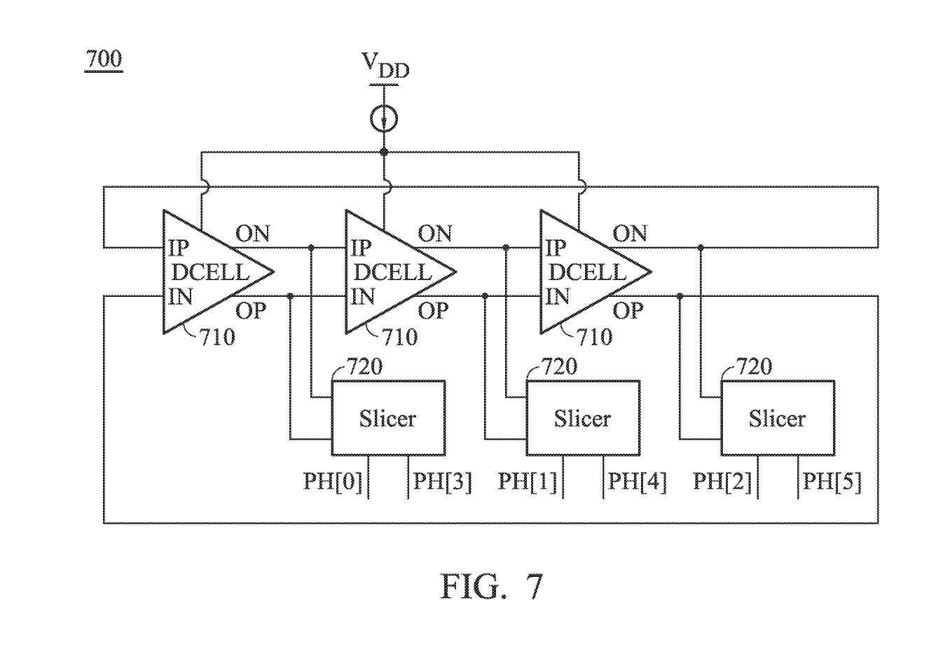

FIG. 7 is a block diagram of a ring oscillator according to another embodiment of the invention. According to an embodiment of the invention, the ring oscillator 700 may comprise a plurality of stages of differential delay cells DCELL 710 and differential slicers 720 coupled in serial. The differential output nodes ON and OP of each delay cell stage 710 are coupled to the differential input nodes IP and IN of a following delay cell stage 710. In this example, the ring oscillator 700 may be a current controlled oscillator (ICO) and there are three stages of delay cells comprised in the ring oscillator 700. It should be noted that the ring oscillator 700 may also be a voltage controlled oscillator, or others, and may also comprise less than or more than three stages of delay cells, and therefore, the invention should not be limited to the structure as shown in FIG. 7.

The differential slicers 720 may be coupled to the differential output nodes ON and OP of a delay cell 710 for receiving the differential output signals from the corresponding delay cell 710, and shaping the differential output signals to generate the oscillating signals with different phases at the corresponding output nodes PH[0] and PH[3], PH[1] and PH[4] and PH[2] and PH[5].

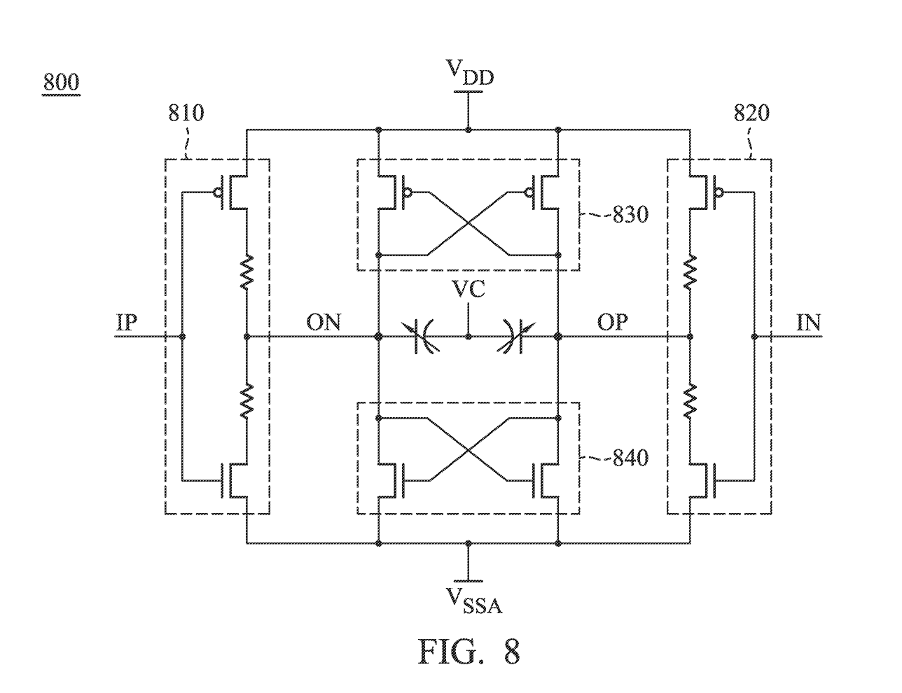

FIG. 8 shows a circuit diagram of a differential delay cell according to an embodiment of the invention. The differential delay cell 800 may comprise an R-inverter 810, with at least one resistive device comprised therein, coupled between the input node IP and the output node ON, an R-inverter 820, with at least one resistive device comprised therein, coupled between the input node IN and the output node OP, two latches 830 and 840 coupled between the output nodes OP and ON, and two varactors coupled to a control voltage VC and the output nodes OP and ON.

The R-inverter 810 may have the same structure as the R-inverter 820. Note that the structures of the R-inverter 810 and the R-inverter 820 may also be designed as the embodiments shown in FIG. 3 to FIG. 6, or other modifications, as long as the resistance can be contributed by the resistive device on the charge path of the inverter circuit when charging the varactors and a discharge path of the inverter circuit when discharging the varactors. The at least one resistive device comprised in the R-inverter 810 and the R-inverter 820 may be utilized to reduce the sensitivity of the delay time t_{d} of the corresponding delay cell to the changes in supply voltage V_{DD} and temperature, resulting in a stable, low-gain and temperature-insensitive ring oscillator. For a detailed discussion of the designs the resistance R contributed by the resistive device, reference may be made to the description of FIG. 2, which is omitted here for brevity.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A ring oscillator, comprising:
a plurality of stages of delay cells coupled in serial, wherein at least one delay cell comprises a first inverter, and wherein the first inverter comprises:
an input node, receiving an input signal;
a first transistor, coupled to a first supply voltage and the input node;
a second transistor, coupled to a second supply voltage and the input node;
an output node, coupled to the first transistor and the second transistor and outputting an output signal; and
at least one resistive device, coupled to the capacitor, the first transistor, and the second transistor.

2. The ring oscillator as claimed in claim 1, wherein the first inverter further comprises a capacitor coupled between the output node and a third supply voltage.

3. The ring oscillator as claimed in claim 1, wherein the resistive device is disposed on a charge path from the first supply voltage to the capacitor or a discharge path from the capacitor to the second supply voltage.

4. The ring oscillator as claimed in claim 1, wherein the resistive device comprises at least a first resistor coupled between the output node and the first supply voltage and a second resistor coupled between the output node and the second supply voltage.

5. The ring oscillator as claimed in claim 1, wherein the resistive device comprises at least a resistor coupled between the output node and a connection node

6. The ring oscillator as claimed in claim 4, wherein the first resistor is electrically connected between a first electrode of the first transistor and the output node.

7. The ring oscillator as claimed in claim 4, wherein the second resistor is electrically connected between a first electrode of the second transistor and the output node.

8. The ring oscillator as claimed in claim 4, wherein the first resistor is electrically connected between the first supply voltage and a second electrode of the first transistor.

9. The ring oscillator as claimed in claim 4, wherein the second resistor is electrically connected between the second supply voltage and a second electrode of the second transistor.

10. The ring oscillator as claimed in claim 1, wherein a resistance contributed by the resistive device is greater than a first turn-on resistance of the first transistor and a second turn-on resistance of the second transistor.

11. The ring oscillator as claimed in claim 1, wherein a resistance contributed by the resistive device has a temperature coefficient complementary to that of a first turn-on resistance of the first transistor and that of a second turn-on resistance of the second transistor.

12. The ring oscillator as claimed in claim 1, wherein the delay cells are differential delay cells and the at least one delay cell further comprises:
a second inverter; having the same structure as the first inverter;
a first latch, coupled between the output nodes of the first inverter and the second inverter; and
a second latch, coupled between the output nodes of the first inverter and the second inverter,
wherein the output nodes of the first inverter and the second inverter form a pair of differential output nodes and the input nodes of the first inverter and the second inverter form a pair of differential input nodes.

13. An inverter circuit, comprising:
an input node, receiving an input signal;
a first transistor, coupled to a first supply voltage and the input node;
a second transistor, coupled to a second supply voltage and the input node;
an output node, coupled to the first transistor and the second transistor and outputting an output signal complementary to the input signal; and
at least one resistive device, contributing a resistance on a charge path when charging the capacitor or a discharge path when discharging the capacitor.

14. The inverter circuit as claimed in claim 13, further comprising a capacitor coupled between the output node and a third supply voltage.

15. The inverter circuit as claimed in claim 14, wherein the charge path starts with the first supply voltage through the first transistor and the capacitor to the third supply voltage, and the discharge path starts with the capacitor through the second transistor to the second supply voltage.

16. The inverter circuit as claimed in claim 13, wherein the resistive device comprises at least a first resistor coupled between the output node and the first supply voltage and a second resistor coupled between the output node and the second supply voltage.

17. The inverter circuit as claimed in claim 13, wherein the resistive device comprises at least a resistor coupled between the output node and a connection node

18. The inverter circuit as claimed in claim 16, wherein the first resistor is electrically connected between a first electrode of the first transistor and the output node.

19. The inverter circuit as claimed in claim 16, wherein the second resistor is electrically connected between a first electrode of the second transistor and the output node.

20. The supply voltage as claimed in claim 16, wherein the first resistor is electrically connected between the first supply voltage and a second electrode of the first transistor.

21. The inverter circuit as claimed in claim 16, wherein the second resistor is electrically connected between the second supply voltage and a second electrode of the second transistor.

22. The inverter circuit as claimed in claim 13, wherein the resistance contributed by the resistive device is greater than twice of a first turn-on resistance of
